(19) United States
(12) Patent Application Publication
(10) Pub. No.: US 2009/0123716 A1
(43) Pub. Date: May 14, 2009

(54) Magnetic Substance-Containing Insulator and Circuit Board and Electronic Device Using the Same

(75) Inventor: Tadahiro Ohmi, Miyagi (JP)

Correspondence Address: FOLEY AND LARDNER LLP;SUITE 500, 3000 K STREET NW, WASHINGTON, DC, 20007, US

(73) Assignee: Tohoku University, Miyagi (JP)

(21) Appl. No.: 11/886,910

(22) PCT Filed: Mar. 17, 2006
(86) PCT No.: PCT/JP2006/305359

§ 371 Date: Sep. 21, 2007

(30) Foreign Application Priority Data
Mar. 22, 2005 (JP) 2005-082653

(51) Int. Cl. H01B 3/00; B05D 5/00; H05K 1/03; B32B 5/16

(52) U.S. Cl. 428/213; 427/130

(57) ABSTRACT

To provide a magnetic substance-containing insulator that can achieve an effect of increasing the permeability without comparatively increasing the mixing concentration of a magnetic substance and, by applying the thus obtained magnetic substance-containing insulator to a circuit board, that can improve the characteristic impedance and achieve an effect of reducing the power consumption, and to provide a circuit board and an electronic component each using such a magnetic substance-containing insulator.

A magnetic substance-containing insulator 10 includes plural magnetic substance particles 1a, 1b and an insulator 2 holding the plural magnetic substance particles 1a, 1b, wherein a group of the magnetic substance particles is composed of plural particle sizes.

### TECHNICAL FIELD

This invention relates to an insulator material and a circuit board for use, for example, as a high-frequency printed wiring board and, more specifically, relates to an insulating material and a circuit board enabling low power consumption, excellent in crosstalk and radiation noise suppression function, and capable of improving the quality of a signal propagating in a line.

### BACKGROUND ART

The signal rise rates have increased due to an improvement in operating speed of LSI, such as CPU, and thus a problem, such as signal reflection and radiation in a line between elements is becoming serious.

With respect to such a problem, wiring called a signal transmission line with controlled characteristic impedance is formed on a circuit board, thereby attempting to suppress signal reflection and crosstalk between elements.

On the other hand, use is generally made of a characteristic impedance of about several tens of Ω to 100Ω and there arises a problem that the power consumption is large at a terminator terminating the line.

For reducing the power consumption, an attempt is made to increase the characteristic impedance of a line, thereby increasing a resistance value of a terminator to reduce the power consumption (see Patent Document 1).

Patent Document 1 discloses that the characteristic impedance is increased by mixing magnetic substance powder into an insulator material forming a circuit board to increase the permeability of the material. Further, Patent Document 1 describes, as examples, that globular, flat, or fiber-shaped powder can be preferably used as the magnetic substance powder to be mixed.

On the other hand, Patent Document 2 discloses that magnetic substance powder is dispersed into a resin to increase its permeability and loss, thereby using it as an electromagnetic wave absorbing sheet.
Patent Document 1: Japanese Unexamined Patent Application Publication (JP-A) No. 2004-087627
Patent Document 2: Japanese Unexamined Patent Application Publication (JP-A) No. H11-354973

### DISCLOSURE OF THE INVENTION

### Problem to be Solved by the Invention

However, it is becoming clear according to the study by the inventors of this invention that there arises a problem that, in the case of using the globular magnetic substance powder, since the demagnetizing factor of each magnetic substance particle increases, the permeability does not easily increase and thus an increase in mixing concentration is required. The larger mixing concentration tends to cause difficulty in terms of production such that uniform dispersibility is difficult to obtain as also disclosed in Patent Document 1.

In Patent Document 2, the magnetic substance is contained for the purpose of absorbing electromagnetic waves using a magnetic loss of the magnetic substance, but there is no specific description about a method of dispersing fine particles of the magnetic substance and, further, it is not intended for reducing the magnetic loss in order to positively transmit the electromagnetic waves.

Therefore, it is a technical object of this invention to provide a magnetic substance-containing insulator that can achieve an effect of increasing the permeability without comparatively increasing the mixing concentration of a magnetic substance and, by applying the thus obtained magnetic substance-containing insulator to a circuit board, that can improve the characteristic impedance and achieve an effect of reducing the power consumption, and to provide a circuit board using such a magnetic substance-containing insulator.

It is another technical object of this invention to provide a magnetic substance-containing insulator that can achieve an effect of increasing the permeability and reducing the magnetic loss without comparatively increasing the mixing concentration of a magnetic substance and, by applying the thus obtained magnetic substance-containing insulator to an electronic component, that can achieve an improvement in component characteristics such as an improvement in Q value, and to provide an electronic component using such a magnetic substance-containing insulator.

It is still another technical object of this invention to provide an electronic device using the foregoing circuit board or the foregoing electronic component.

It is a still further technical object of this invention to provide a circuit board containing a magnetic substance so as not to absorb an electromagnetic wave but to positively transmit the electromagnetic wave, and to provide a manufacturing method thereof.

### Means for Solving the Problem

According to one aspect of the present invention, there is provided a magnetic substance-containing insulator which includes plural magnetic substance particles and an insulator holding the plural magnetic substance particles. In the magnetic substance-containing insulator, the magnetic substance particles contain groups having particle sizes different from each other.

According to another aspect of the present invention, there is provided a magnetic substance-containing insulator which includes plural magnetic substance particles and an insulator holding said plurality of magnetic substance particles. In the magnetic substance-containing insulator, a particle size distribution in a group of said magnetic substance particles has plural peaks.

According to still another aspect of the present invention, there is provided a method of manufacturing a magnetic substance-containing insulator obtained by mixing together a resin varnish and a slurry in which a magnetic substance is dispersed in a solvent and by performing coating, drying, and firing. In the method of manufacturing a magnetic substance-containing insulator, a process of manufacturing the slurry includes the steps of manufacturing a dispersion solvent in which a surfactant is added to the solvent and mixing magnetic substance fine powder to said dispersion solvent. The step of mixing the magnetic substance fine powder includes the sub-steps of performing the screw stirring, irradiating an ultrasonic wave having a frequency of less than 100 kHz, and irradiating an ultrasonic wave having a frequency of 100 kHz or more.

### EFFECT OF THE INVENTION

According to a magnetic substance-containing insulator of this invention, since plural magnetic substance powders having different particle sizes are mixed in an insulator, it is possible to achieve the effect of increasing the permeability without comparatively increasing the mixing concentration of the magnetic substance and, by applying the thus obtained magnetic substance-containing insulator to a circuit board, it is possible to improve the characteristic impedance and to achieve the effect of reducing the power consumption.

Further, according to the magnetic substance-containing insulator of this invention, it is possible to achieve the effect of increasing the permeability without comparatively increasing the mixing concentration of the magnetic substance and, by applying the thus obtained magnetic substance-containing insulator to an electronic component, it is possible to achieve an improvement in component characteristics, such as an improvement in Q value.

Further, in this invention, by performing the firing while carrying out the pressing under reduced pressure, spaces among magnetic substance particles are reduced utilizing the flow of a resin caused by the pressing pressure while facilitating desorption of a solvent, so that dense filling of the magnetic substance is enabled. Therefore, it is possible to simultaneously achieve an improvement in permeability and a reduction in loss caused by capability of reducing local aggregation.

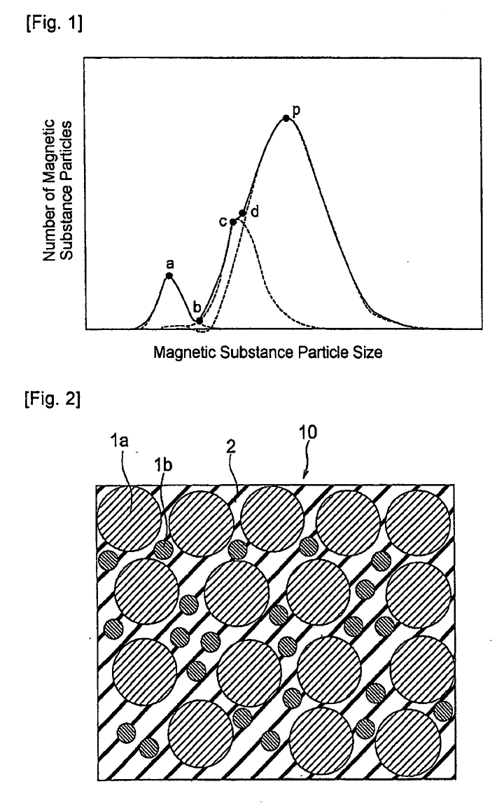

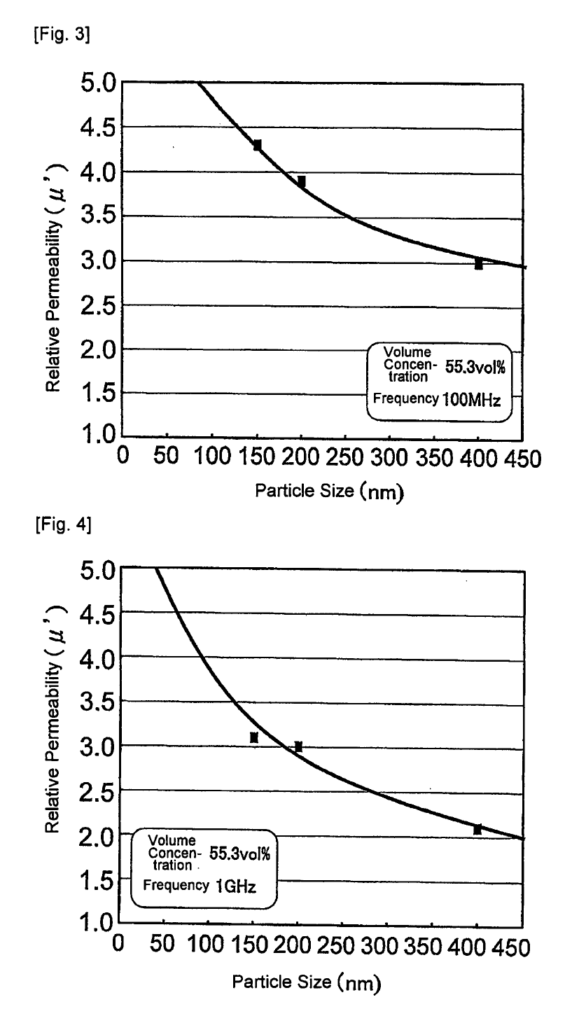

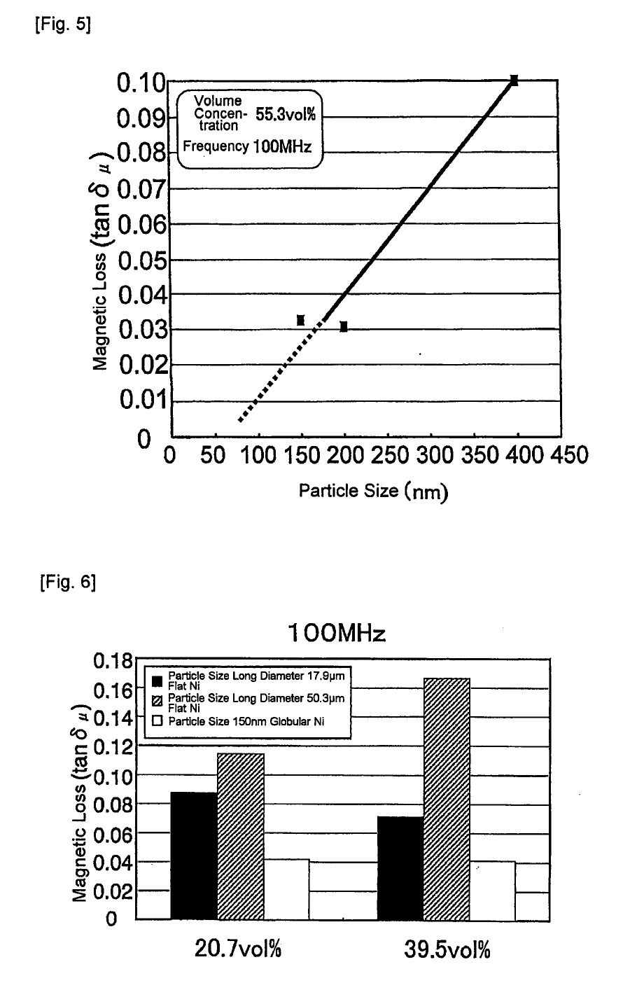

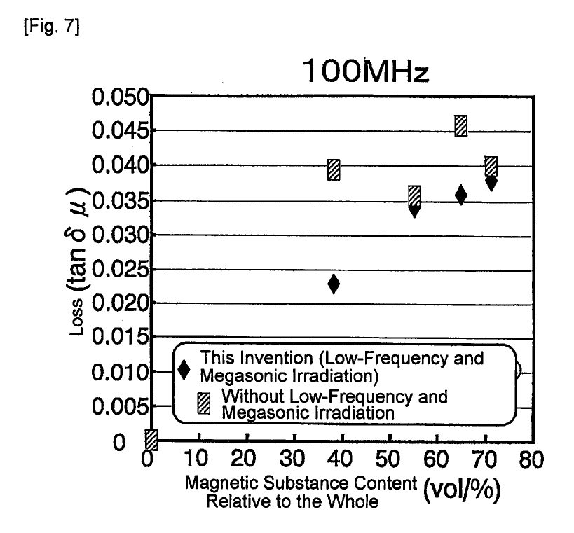

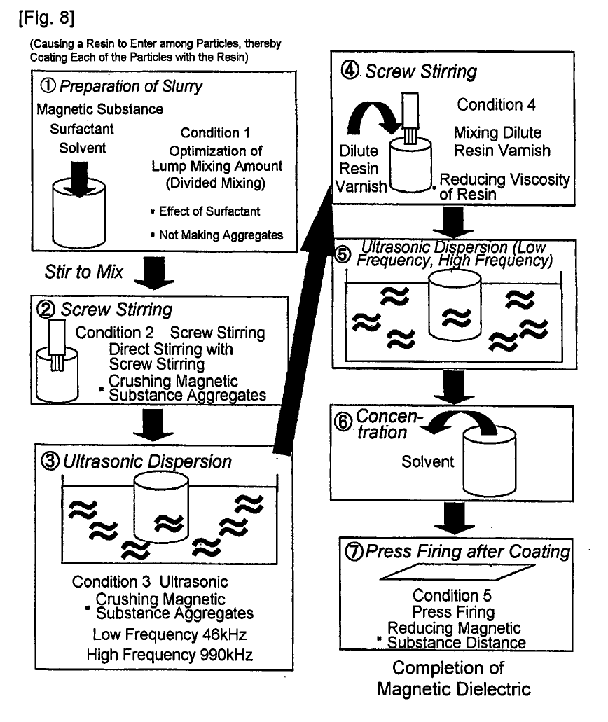

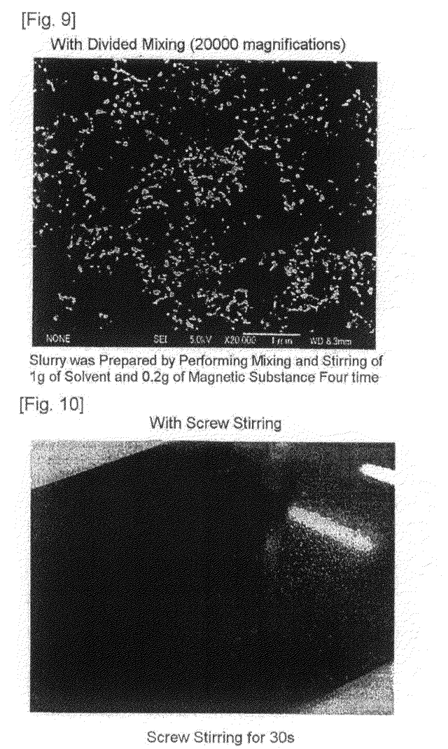

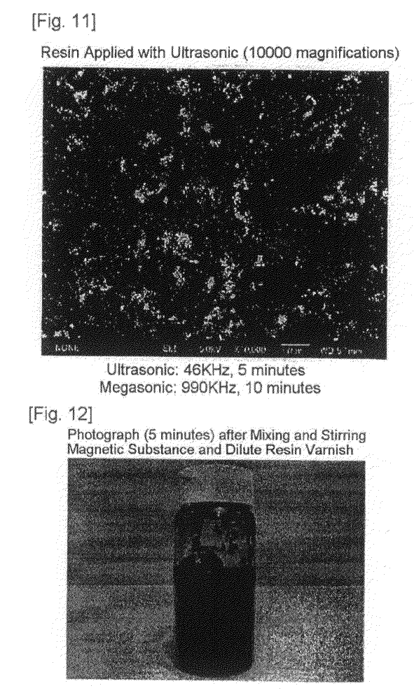

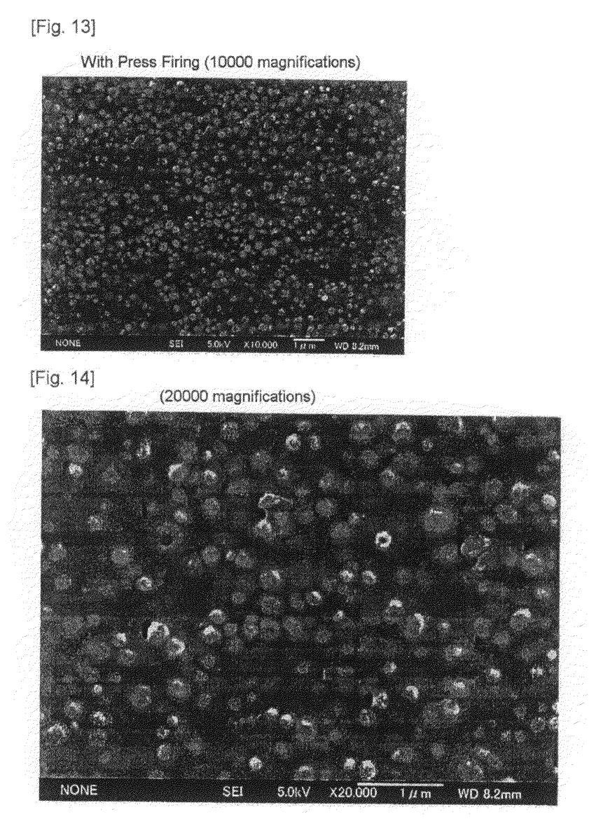

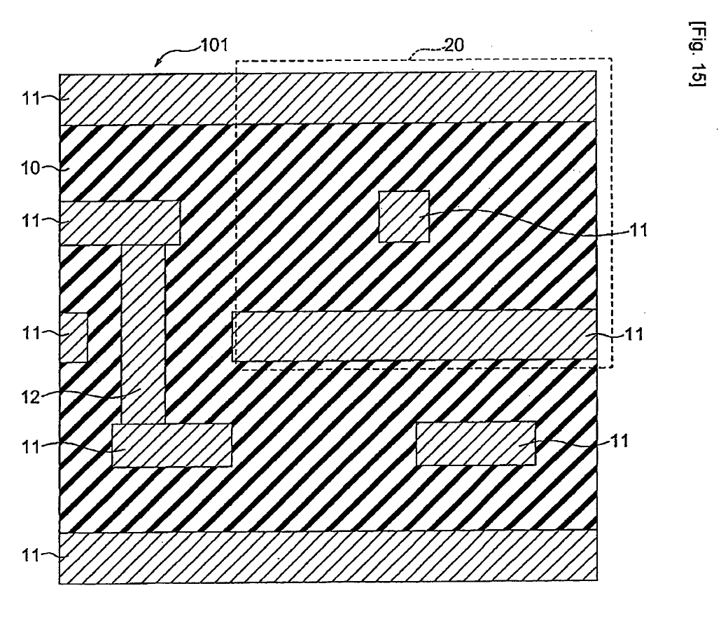

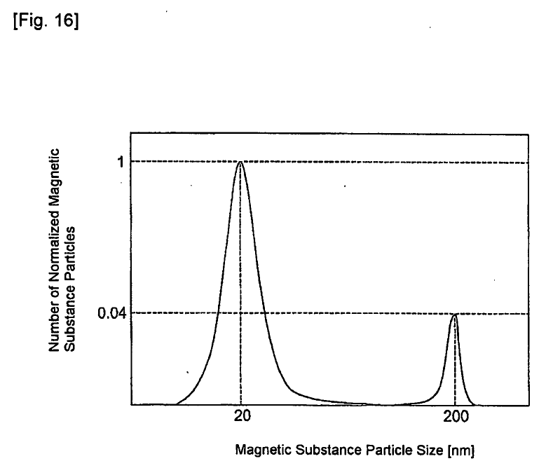

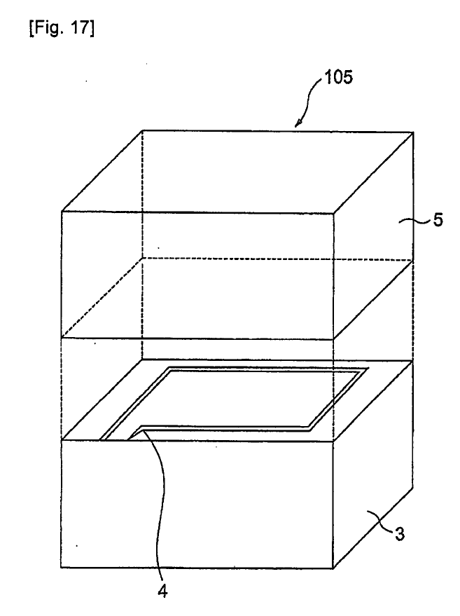

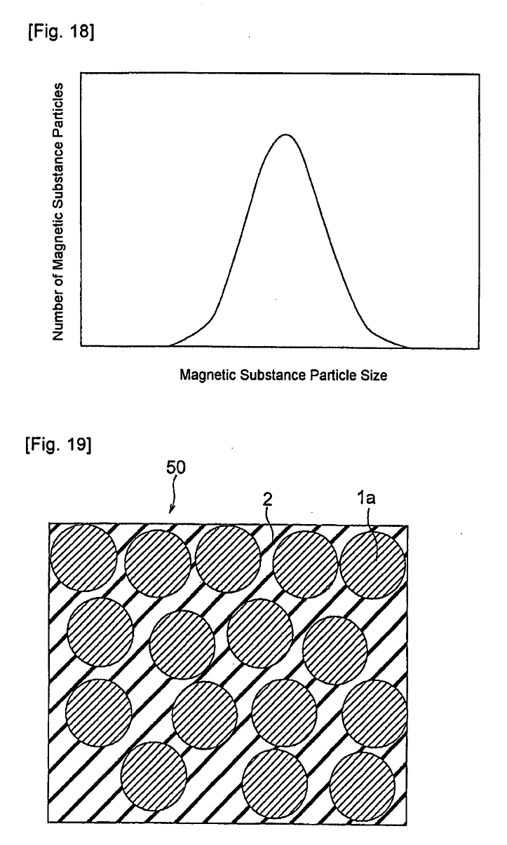

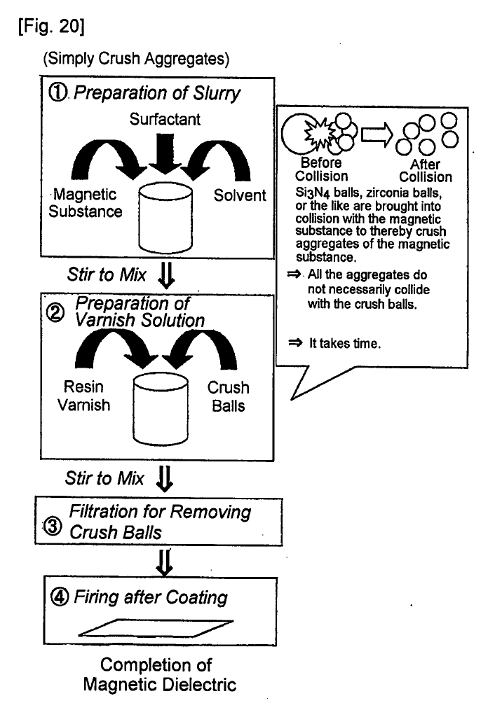

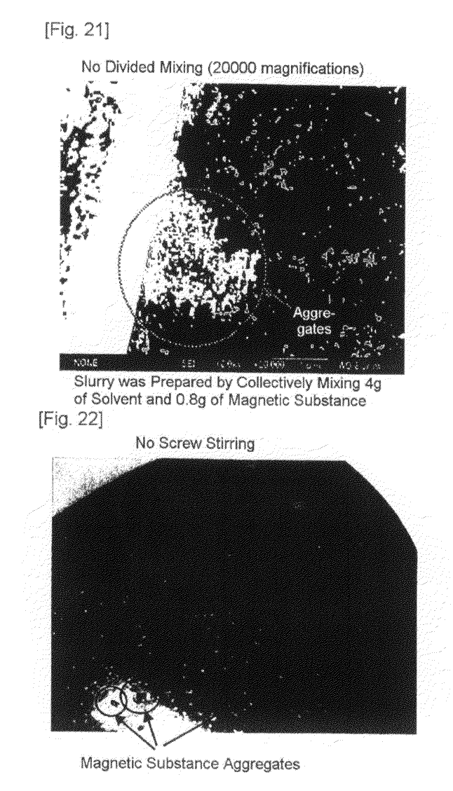

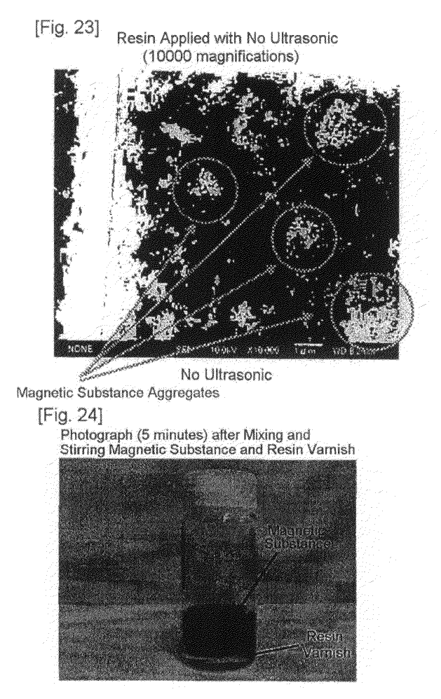

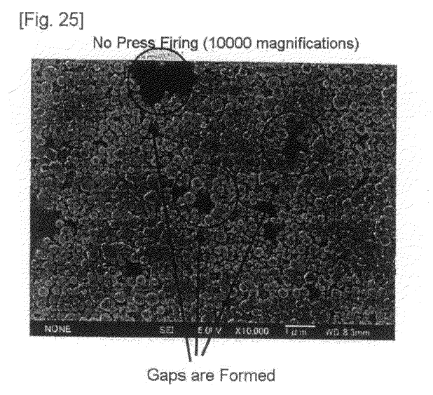

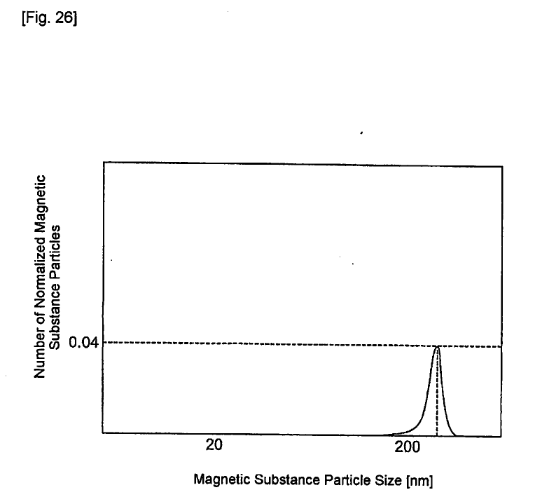

### BRIEF DESCRIPTION OF THE DRAWINGS

[FIG. 1] A diagram showing the relationship between the particle size and the number of particles of a magnetic substance in a magnetic substance-containing insulator of this invention.

[FIG. 2] A diagram exemplarily showing an insulator containing magnetic substance powder having plural particle sizes according to this invention.

[FIG. 3] A diagram showing the relationship between the particle size of magnetic powder (Ni) and the relative permeability (μ′) thereof at 100 MHz.

[FIG. 4] A diagram showing the relationship between the particle size of magnetic powder (Ni) and the relative permeability (μ′) thereof at 1 GHz.

[FIG. 5] A diagram showing the relationship between the particle size of magnetic powder (Ni) and the magnetic loss (tan δ_{μ}) thereof.

[FIG. 6] A diagram showing the relationship between the magnetic loss (tan δ_{μ}) of flat powder and that of globular powder, which is an example where flat fine nickel powders having a thickness of 300 nm and average long diameters of 17.9 μm and 50.3 μm are mixed, respectively.

[FIG. 7] A diagram showing the magnetic loss when 44 kHz and 990 kHz ultrasonic irradiation is performed or not performed after screw stirring in the manufacture of a magnetic substance-containing resin.

[FIG. 8] A diagram showing respective processes of a method of manufacturing a magnetic dielectric substance according to this invention.

[FIG. 9] A scanning electron microphotograph showing the result of dispersion according to divided mixing.

[FIG. 10] An external appearance photograph after coating a magnetic substance in the case where screw stirring was performed for 30 seconds.

[FIG. 11] A scanning electron microphotograph showing a resin dispersion state when ultrasonic irradiation (ultrasonic: 46 kHz, 5 minutes; megasonic: 990 kHz, 10 minutes) was carried out.

[FIG. 12] A photograph showing a state 5 minutes after mixing a diluted varnish to a magnetic substance and stirring them.

[FIG. 13] A scanning electron microphotograph of a magnetic dielectric substance containing 65 vol % fine nickel powder of 150 nm with press firing performed.

[FIG. 14] A scanning electron microphotograph showing the result of dispersion including all the factors of the foregoing conditions 1 to 5.

[FIG. 15] A sectional view showing the structure of a circuit board in Example 1 of this invention.

[FIG. 16] A diagram showing a magnetic substance particle size distribution in a magnetic substance-containing insulator I of this invention.

[FIG. 17] A schematic exploded perspective view showing an electronic component according to an example of this invention.

[FIG. 18] A diagram showing the relationship between the particle size and the number of particles of a magnetic substance in a general magnetic substance-containing insulator for comparison.

[FIG. 19] A diagram exemplarily showing an insulator containing magnetic substance powder having a single particle size for comparison.

[FIG. 20] A diagram showing a general technique of a method of manufacturing a magnetic dielectric substance.

[FIG. 21] A scanning electron microphotograph showing a dispersion state when no divided mixing is performed.

[FIG. 22] An external appearance photograph after coating a magnetic substance in the case of no screw stirring.

[FIG. 23] A scanning electron microphotograph showing a resin dispersion state in the case of no ultrasonic irradiation.

[FIG. 24] A photograph showing a state 5 minutes after mixing a varnish resin to a magnetic substance and stirring them.

[FIG. 25] A scanning electron microphotograph of a magnetic dielectric substance containing 65 vol % fine nickel powder of 150 nm with no press firing.

[FIG. 26] A diagram showing a magnetic substance particle size distribution in a magnetic substance-containing insulator II of according to a comparative example.

### DESCRIPTION OF SYMBOLS

1a, 1b magnetic substance powder
2 insulating material
3, 5 magnetic substance-containing insulator board
4 inductance line (coil pattern)
10 magnetic substance-containing insulator
11 metal line
12 connecting portion
101 circuit board
105 chip inductor

### BEST MODE FOR CARRYING OUT THE INVENTION

This invention will be described in further detail.

A magnetic substance-containing insulator according to a first invention of this invention includes plural magnetic substance particles and an insulator holding the plural magnetic substance particles. In the magnetic substance-containing insulator, a group of the magnetic substance particles includes at least plural particle sizes.

The insulator may be an inorganic substance or a synthetic resin.

This synthetic resin preferably includes at least one kind selected from the group consisting of an epoxy resin, a phenol resin, a polyimide resin, a polyester resin, a fluorine resin, a denatured polyphenylether resin, a bismaleimide triazine resin, a denatured polyphenylene oxide resin, a silicon resin, an acrylic resin, a benzocyclobutene resin, a polyethylene naphthalate resin, a polycycloolefin resin, a polyolefin resin, a cyanate ester resin, a melamine resin, and an acrylic resin. Further, in the magnetic substance-containing insulator of this invention, a loss tangent tan δ_{μ} indicative of a magnetic loss is preferably 0.1 or less at a frequency of 100 MHz.

Further, a circuit board of this invention includes at least the foregoing magnetic substance-containing insulator.

Further, an electronic device of this invention includes at least this circuit board.

Further, an electronic component of this invention comprises at least any one of the foregoing magnetic substance-containing insulators. Further, an electronic device of this invention comprises at least this electronic component.

Further, a magnetic substance-containing insulator according to a second invention of this invention includes plural magnetic substance particles and an insulator holding the plura magnetic substance particles. In the magnetic substance-containing insulator, a particle size distribution in a group of the magnetic substance particles has plural peaks.

In this magnetic substance-containing insulator, the peak, on a small particle size side, of the plurality of peaks is present preferably in a range of 5 nm to 100 nm. Further, in the magnetic substance-containing insulator, the insulator is preferably an inorganic substance or a synthetic resin. As this synthetic resin, use can be made of at least one kind selected from the group consisting of an epoxy resin, a phenol resin, a polyimide resin, a polyester resin, a fluorine resin, a denatured polyphenylether resin, a bismaleimide triazine resin, a denatured polyphenylene oxide resin, a silicon resin, an acrylic resin, a benzocyclobutene resin, a polyethylene naphthalate resin, a polycycloolefin resin, a polyolefin resin, a cyanate ester resin, a melamine resin, and an acrylic resin.

Further, in any one of the magnetic substance-containing insulators, a loss tangent tan δ_{μ} indicative of a magnetic loss is preferably 0.1 or less at a frequency of 100 MHz.

Further, a circuit board according to the second invention of this invention comprises at least any one of the foregoing magnetic substance-containing insulators.

Further, an electronic device according to the second invention of this invention includes at least this circuit board.

Further, an electronic component according to the second invention of this invention includes at least any one of the foregoing magnetic substance-containing insulators.

Further, an electronic device according to the second invention of this invention includes at least this electronic component.

Further, a method of manufacturing a magnetic substance-containing insulator according to a third invention of this invention is a method of manufacturing a magnetic substance-containing insulator obtained by mixing together a resin varnish and a slurry in which a magnetic substance is dispersed in a solvent and by performing coating, drying, and firing. In the method, a process of manufacturing the slurry includes the steps of manufacturing a dispersion solvent in which a surfactant is added to the solvent and mixing magnetic substance fine powder to the dispersion solvent. The step of mixing the magnetic substance fine powder includes the sub-steps of performing the screw stirring, irradiating an ultrasonic wave having a frequency of less than 100 kHz, and irradiating an ultrasonic wave having a frequency of 100 kHz or more.

In this method of manufacturing the magnetic substance-containing insulator, the firing is preferably press firing performed under reduced pressure.

Now, an embodiment of this invention will be described with reference to the drawings.

FIG. 1 is a diagram showing the relationship between the particle size and the number of particles of a magnetic substance in a magnetic substance-containing insulator of this invention. FIG. 18 is a diagram showing the relationship between the particle size and the number of particles of a magnetic substance in a general magnetic substance-containing insulator for comparison.

As shown in FIG. 18, the particle size distribution of magnetic substance powder generally takes the form of a normal distribution. It is a well-known fact that the smaller a half width representing a distribution width of the particle size in the number of particles half that at a point where the number of particles becomes maximum, the more uniform the particle size.

Referring to FIG. 1, the magnetic substance-containing insulator of this invention is in contrast to the conventional magnetic substance-containing insulator shown in FIG. 18 in that there is an inflection point (point a, b, c, d) at least any point on a distribution curve present on both sides of a point (point p) where the number of particles becomes maximum. In the case where there exists the inflection point on the distribution curve excluding the maximum value (point p) as described above, an actual distribution function indicated by a solid line can be obtained by combining plural different distribution curves each in the form of a normal distribution as indicated by dotted lines in FIG. 1.

In the foregoing example, a distribution function is expressed as in the form of a normal distribution. However, this also applies to a function as long as it has an upward convex shape with a maximum point, such as in the form of a quadratic function or a Gaussian distribution.

Therefore, in this invention “having plural peaks” represents that an inflection point at least any point exist on an obtained distribution curve excluding a point where the number of particles becomes maximum.

By mixing the magnetic substance having plural particle sizes as described above, the particles can be filled in magnetic substance unfilled regions formed between the particles. Therefore, even if the magnetic substance particles are not dispersed at high concentration, it is possible to obtain the effect of increasing the permeability.

FIGS. 2 and 19 are explanatory diagrams showing it. FIG. 2 is a diagram exemplarily showing an insulator containing magnetic substance powder having plural particle sizes according to this invention, and FIG. 19 is a diagram exemplarily showing an insulator containing magnetic substance powder having a single particle size for comparison. From a comparison between FIGS. 2 and 19, it is seen that, by mixing particles of magnetic substances 1a, 1b having plural particle sizes according to this invention, the magnetic substance can be filled in unfilled regions.

Herein, an insulator 2 used in this invention may be an inorganic substance, such as silica, alumina, aluminum nitride, or silicon nitride, or may be a synthetic resin, such as an epoxy resin, a phenol resin, a polyimide resin, a polyester resin, a fluorine resin, a denatured polyphenylether resin, a bismaleimide triazine resin, a denatured polyphenylene oxide resin, a silicon resin, an acrylic resin, a benzocyclobutene resin, a polyethylene naphthalate resin, a polycycloolefin resin, a polyolefin resin, a cyanate ester resin, a melamine resin, or an acrylic resin.

Among these insulator materials, when using it as a circuit board material, it is preferable that the permittivity be low in terms of increasing the characteristic impedance, and thus the fluorine resin, the polyolefin resin, or the like is preferably selected. On the other hand, when using it as an electronic component material, the permittivity may be properly selected according to a use of an electronic component. In the case of an inductance or the like that requires low-permittivity characteristics, the polyolefin resin or the fluorine resin is preferably selected, while, in the case of a capacitor, an antenna element, or the like that requires high-permittivity characteristics, use can be properly made of the silica, the alumina, a mixture of such an inorganic substance and an organic substance, or the like.

Therefore, according to a magnetic substance-containing insulator of this invention, since plural magnetic substance powders having different particle sizes are mixed in an insulator, it is possible to achieve the effect of increasing the permeability without comparatively increasing the mixing concentration of the magnetic substance and, by applying the thus obtained magnetic substance-containing insulator to a circuit board, it is possible to improve the characteristic impedance and to achieve the effect of reducing the power consumption. Further, according to the magnetic substance-containing insulator of this invention, it is possible to achieve the effect of increasing the permeability without comparatively increasing the mixing concentration of the magnetic substance and, by applying the thus obtained magnetic substance-containing insulator to an electronic component, it is possible to achieve an improvement in component characteristics, such as an improvement in Q value.

As a result of a further study, the present inventors have elucidated that, given that f represents a signal frequency, μ a permeability of a magnetic substance fine particle, and a σ conductivity of the magnetic substance fine particle, the effect of reducing the magnetic loss appears when the diameter of the magnetic substance particle is smaller than a skin depth expressed as δ=(1/(πfμσ))^{1/2}.

For example, in the case of fine nickel particles, given that the relative permeability is 200 and the conductivity is 14.3×10⁻⁶, the skin depth is 900 nm and therefore, as the particle size becomes smaller than it, generation of an eddy current decreases and thus the magnetic loss can be reduced. Conversely, the result is obtained that the relative permeability increases as the particle size decreases.

As shown in FIGS. 3 and 4, it is seen that as the particle size of magnetic powder (Ni) decreases, the relative permeability (μ′, μ″) increases both at 100 MHz and 1 GHz. Further, as shown in FIG. 5, it is seen that as the particle size of magnetic powder (Ni) decreases, the magnetic loss (tan δ_{μ}) gradually decreases.

This tendency is not limited to globular magnetic substance particles, but also applies to flat magnetic substance particles.

FIG. 6 shows an example in which flat fine nickel powders having a thickness of 300 nm and average long diameters of 17.9 μm and 50.3 μm are mixed, respectively. As a reference, the results are shown at the same concentrations in the case of globular nickel powder having an average diameter of 150 nm. It is seen that as the particle size decreases, the magnetic loss can be reduced.

Further, it has been elucidated that the loss can be reduced by a dispersion method of magnetic substance particles. It has been elucidated that if the dispersibility is poor so that aggregates exist, i.e. gatherings, of plural magnetic substance particles, the loss increases or variation in quality increases among products.

FIG. 7 shows the magnetic loss when 44 kHz and 990 kHz ultrasonic irradiation is performed or not performed after screw stirring in the manufacture of a magnetic substance-containing resin and is a diagram showing the relationship between the magnetic substance content and the loss at that time. It is seen that a reduction in loss and uniform production can be achieved by performing the ultrasonic irradiation.

Next, a description will be made as regards a magnetic dielectric substance (magnetic substance-containing insulator) manufacturing method for uniformly dispersing a magnetic substance according to this invention.

FIG. 8 is a diagram showing respective processes of the magnetic dielectric substance manufacturing method according to this invention. On the other hand, FIG. 20 is a diagram showing a general technique of a magnetic dielectric manufacturing method.

As shown in FIG. 8, the general technique simply crushes aggregates and, at first, prepares a slurry by adding a surfactant to a magnetic substance and a solvent. Then, after mixing by stirring, a resin, a varnish, or the like is added and crush balls are added and, then, mixing is performed by stirring. Herein, Si₃N₄ balls, zirconia balls, or the like, as the crush balls, are brought into collision with the magnetic substance to thereby crush the magnetic substance. However, there is a drawback that all the aggregates do not necessarily collide with the crush balls and it takes time.

Further, filtration is carried out for removing the crush balls and then firing is carried out after coating on a substrate or the like, so that a magnetic dielectric substance is completed.

On the other hand, the processes of the magnetic dielectric substance (magnetic substance-containing insulator) manufacturing method according to this invention are a method of causing a resin to enter among particles so as to coat each of the particles with the resin and, at first, prepare a slurry by mixing together a magnetic substance, a surfactant, and a solvent. As condition 1, it is necessary to optimize a lump mixing amount and divided mixing is carried out. Herein, as an effect of the surfactant, an operation and effect of not making aggregates can be performed. FIG. 9 is a scanning electron microphotograph showing the result of dispersion according to the divided mixing, while FIG. 21 is a scanning electron microphotograph showing a dispersion state when no divided mixing was performed. As either of the samples, a magnetic dielectric substance was manufactured which has a particle size of 20 nm and containing 4.95 vol % ultrafine iron particles. In FIG. 9, a slurry was prepared by performing, four times, mixing and stirring of 0.2 g of the magnetic substance with respect to 1 g of the solvent. On the other hand, in FIG. 21, a slurry was prepared by collectively mixing together 4 g of the solvent and 0.8 g of the magnetic substance. A comparison between FIGS. 9 and 21 shows that the dispersion state is better when the magnetic substance is mixed little by little.

Then, after mixing by stirring, screw stirring is carried out. Herein, as condition 2, crushing of magnetic substance aggregates can be performed by directly stirring them with the screw stirring. Herein, FIG. 10 shows an external appearance photograph after coating the magnetic substance in the case where the screw stirring was performed for 30 seconds, while FIG. 22 shows an external appearance photograph after coating the magnetic substance in the case of no screw stirring. In either case, a magnetic dielectric substance was manufactured which has a particle size of 20 nm and containing 4.95 vol % ultrafine iron particles. From a comparison between FIGS. 10 and 22, it has been found that aggregates so large as to be visible remain on the actual film surface in the case of no screw stirring.

Then, ultrasonic dispersion is carried out. Herein, as condition 3, crushing of magnetic aggregates is performed at a low frequency of 46 kHz and at a high frequency of 990 kHz. FIG. 11 is a scanning electron microphotograph showing a resin dispersion state when ultrasonic irradiation (ultrasonic: 46 kHz, 5 minutes; megasonic: 990 kHz, 10 minutes) was carried out, while FIG. 23 is a scanning electron microphotograph showing a resin dispersion state in the case of no ultrasonic irradiation. In either case, a magnetic dielectric substance was manufactured which has a particle size of 20 nm and containing 4.95 vol % ultrafine iron particles.

From a comparison between FIGS. 11 and 23, it has been found that the dispersion state is better with the ultrasonic irradiation than with no ultrasonic irradiation.

Then, a dilute resin varnish is mixed and then screw stirring is carried out. Herein, as condition 4, a comparison was made between the case where the resin varnish was diluted and the case where the resin varnish was not diluted. FIG. 12 is a photograph showing a state 5 minutes after mixing the diluted varnish to the magnetic substance and stirring them, while FIG. 24 is a photograph showing a state 5 minutes after mixing the varnish resin to the magnetic substance and stirring them. In either case, a magnetic dielectric substance was manufactured which has a particle size of 20 nm and containing 4.95 vol % ultrafine iron particles.

From a comparison between FIGS. 12 and 24, it has been found that it is necessary to dilute the resin varnish to thereby reduce the viscosity thereof. The reason therefor is that if the viscosity of the resin varnish is very high, it is difficult for the magnetic substance to uniformly enter the resin varnish and, particularly at a high concentration, the resin and the magnetic substance layer are separated from each other.

Then, ultrasonic dispersion by low frequency and high frequency is carried out. Further, the solvent is volatilized so as to be concentrated. Subsequently, pressing and firing are performed after coating. Herein, as condition 5, an effect of the press firing was examined. FIG. 13 is a scanning electron microphotograph of a magnetic dielectric substance containing 65 vol % fine nickel powder of 150 nm with the press firing performed, while FIG. 25 is a scanning electron microphotograph of a magnetic dielectric substance containing 65 vol % fine nickel powder of 150 nm with no press firing. From a comparison between FIGS. 13 and 25, it has been found that holes disappeared by the pressing.

FIG. 14 is a scanning electron microphotograph showing the result of dispersion including all the factors of the foregoing conditions 1 to 5. As shown in FIG. 14, in the case where a magnetic dielectric substance containing 65 vol % fine nickel powder of 200 nm is manufactured, it can be judged that the resin enters among all the particles and thus the particles are dispersed well.

In the manufacturing method of this invention as described above, by performing the firing while carrying out the pressing under reduced pressure, spaces among the magnetic substance particles are reduced utilizing the flow of the resin caused by the pressing pressure while facilitating desorption of the solvent, so that dense filling of the magnetic substance is enabled. Therefore, it is possible to simultaneously achieve an improvement in permeability and a reduction in loss caused by capability of reducing local aggregation.

### EXAMPLES

Hereinbelow, Examples of this invention will be described.

### Example 1

In Example 1 of this invention, an example of applying this invention to a circuit board will be described using FIG. 15. FIG. 15 is a sectional view showing the structure of a circuit board in Example 1 of this invention. Referring to FIG. 15, the circuit board includes a magnetic substance-containing insulator 10, plural metal lines 11, and a connecting portion 12 connecting these metal lines 10 together and was fabricated by the generally known build-up method.

The magnetic substance-containing insulator 10 in this circuit board 101 was fabricated in the following manner. First magnetic substance powder having an average particle size of 20 nm (ultrafine Fe powder manufactured by Shinku Yakin Co., Ltd.) and second magnetic substance powder having an average particle size of 200 nm (Ni powder manufactured by JFE Mineral Co., Ltd.) were mixed little by little into a dispersion solution in which a higher fatty acid ester as a surfactant was dissolved in a 4:3 mixed solution of xylene and cyclopentanon and, after performing planetary stirring, screw stirring was carried out using a homogenizer. The shaft rotation speed for the screw stirring was set to 1000 rpm. Then, ultrasonic waves of 44 kHz and 990 kHz were each irradiated to this solution for 5 minutes, thereby obtaining a slurry solution. The slurry solution thus obtained and a varnish obtained by dissolving, into a solvent, 100 parts of a polycycloolefin resin (denatured ring-opened polymer of norbornene-type cycloolefin (Tg=170° C.)), 40 parts of a bisphenol-based curing agent, and 0.1 parts of an imidazole-based curing accelerator and then by dilution to a solid matter ratio of 10% or less were uniformly mixed together by planetary stirring and irradiation of an ultrasonic wave of 44 kHz and an ultrasonic wave of 990 kHz each for 5 minutes.

Then, the obtained mixed solution was introduced into a rotary evaporator to evaporate the solvent at 75° C. and 70 Torr (i.e. 1.02 MPa), thereby obtaining the viscosity that enables coating by a doctor blade. The mixed solution thus obtained was formed into a film by the doctor blade method and then dried at normal pressure at 90° C. for 5 minutes.

The film precursor thus obtained was subjected to press firing using a vacuum press machine. The pressing conditions were 160° C., 3 MPa, and 1 hour, thereby obtaining a magnetic substance-containing insulator having a thickness of 100 μm (which will be called a magnetic substance-containing insulator I). The magnetic substance powder dispersion amount was in the ratio of 100 weight parts of the first magnetic substance powder and 500 weight parts of the second magnetic substance powder with respect to 100 weight parts of the component weight, excluding the solvent, of the varnish. The relative permeability pr and the magnetic loss tan δ_{μ} of this magnetic substance were measured by the parallel line method to be μr=10 and tan δ_{μ}=0.02 at 100 MHz.

Magnetic substance particle size distribution in the magnetic substance-containing insulator I was observed and there was obtained a particle size distribution curve as shown in FIG. 16.

Although the foregoing magnetic substance powders were used in Example 1, this invention is not limited thereto and use may be made of metal magnetic substance powder such as Co, an Fe, Ni, or Co alloy, an oxide magnetic substance such as ferrite, or the like.

For comparative evaluation, a magnetic substance-containing insulator (magnetic substance-containing insulator II) was prepared in which 500 weight parts of only the second magnetic substance powder were dispersed in the same varnish as described above with respect to 100 weight parts of the component weight, other than the solvent, of the varnish. The relative permeability of this magnetic substance-containing insulator was μr=4. Magnetic substance particle size distribution in this magnetic substance-containing insulator 2 was observed and FIG. 26 was obtained.

Circuit boards 101 shown in FIG. 15 were fabricated using the foregoing two kinds of magnetic substance-containing insulators, respectively, and striplines having a line width of 10 μm were formed, thereby measuring the characteristic impedance Z0. As a result, Z0=500Ω in the case of the magnetic substance-containing insulator I according to this invention and Z0=300Ω in the case of the magnetic substance-containing insulator II according to the comparative example.

### Example 2

In Example 2 of this invention, an example of applying this invention to an electronic component will be described using FIG. 17. FIG. 17 is a schematic diagram showing a chip inductor 105 as an electronic component according to an example of this invention. Referring to FIG. 17, the chip inductor 105 comprises a magnetic substance-containing insulator board 3 and an inductance line 4. The inductance line 4 was obtained by laminating a copper foil with a thickness of 20 μm on the magnetic substance-containing insulator board 3 and patterning the copper foil by the photolithography method. The line width was set to 100 μm and the line was in the form of a square coil with one turn. A magnetic substance-containing insulator board 5 being the same as the magnetic substance-containing insulator board 3 was attached onto the coil under pressure by the pressing method and cutting was performed into 1.5 mm square to extract electrodes, thereby obtaining the chip inductor.

The magnetic substance-containing insulators in this chip inductor were fabricated in the same manner as in the foregoing Example 1. Chip inductors were fabricated using magnetic substance-containing insulators 1 and 2, respectively, each obtained by stacking plural magnetic substance-containing insulators fabricated in Example 1 and each having a thickness of 1 mm, and Q values were compared.

Each side of a coil was set to 1 mm in the case of the magnetic substance-containing insulator I and 12.2 nH was obtained at 100 MHz. In this event, 0.04Ω was obtained as a DC resistance value. Therefore, 30.5 was obtained as a Q value. On the other hand, the inductor was fabricated using the magnetic substance-containing insulator II so that 12.23 nH was similarly obtained at 100 MHz and, in this case, each side of a coil was 1.67 mm. In this event, 0.067Ω was obtained as a DC resistance.

Therefore, 18.2 was obtained as a Q value.

As described above, according to the magnetic substance-containing insulator in the Examples of this invention, since plural magnetic substance powders having different particle sizes are mixed in the insulator, it is possible to achieve the effect of increasing the permeability without comparatively increasing the mixing concentration of the magnetic substance and, by applying the thus obtained magnetic substance-containing insulator to a circuit board, it is possible to improve the characteristic impedance and to achieve the effect of reducing the power consumption.

Further, according to the magnetic substance-containing insulator in the embodiment of this invention, it is possible to achieve the effect of increasing the permeability without comparatively increasing the mixing concentration of the magnetic substance and, by applying the thus obtained magnetic substance-containing insulator to an electronic component, it is possible to achieve an improvement in component characteristics such as an improvement in Q value.

### INDUSTRIAL APPLICABILITY

As described above, a magnetic substance-containing insulator according to this invention is applied to a circuit board, an electronic component, or an electronic device using it.

1. A magnetic substance-containing insulator comprising plural magnetic substance particles and an insulator holding said plural magnetic substance particles, wherein said magnetic substance particles comprises groups having particle sizes different from each other.

2. A magnetic substance-containing insulator according to claim 1, wherein said insulator is an inorganic substance.

3. A magnetic substance-containing insulator according to claim 2, wherein a loss tangent tan δ_{μ} indicative of a magnetic loss is 0.1 or less at a frequency of 100 MHz.

4. A magnetic substance-containing insulator according to claim 1, wherein said insulator is a synthetic resin.

5. A magnetic substance-containing insulator according to claim 4, wherein said synthetic resin comprises at least one kind selected from the group consisting of an epoxy resin, a phenol resin, a polyimide resin, a polyester resin, a fluorine resin, a denatured polyphenylether resin, a bismaleimide triazine resin, a denatured polyphenylene oxide resin, a silicon resin, an acrylic resin, a benzocyclobutene resin, a polyethylene naphthalate resin, a polycycloolefin resin, a polyolefin resin, a cyanate ester resin, a melamine resin, an acrylic resin, and a liquid-crystal resin.

6. A magnetic substance-containing insulator according to claim 5, wherein a loss tangent tan δ_{μ} indicative of a magnetic loss is 0.1 or less at a frequency of 100 MHz.

7. A circuit board comprising at least the magnetic substance-containing insulator according to claim 1.

8. An electronic device comprising at least the circuit board according to claim 7.

9. An electronic component comprising at least the magnetic substance-containing insulator according to claim 1.

10. An electronic device characterized by comprising at least the electronic component according to claim 9.

11. A magnetic substance-containing insulator comprising plural magnetic substance particles and an insulator holding said plurality of magnetic substance particles, wherein a particle size distribution in a group of said magnetic substance particles has plural peaks.

12. A magnetic substance-containing insulator according to claim 11, wherein the peak, on a small particle size side, of said plural peaks is present in a range of 5 nm to 100 nm.

13. A magnetic substance-containing insulator according to claim 11, wherein said insulator is an inorganic substance.

14. A magnetic substance-containing insulator according to claim 13, wherein a loss tangent tan δ_{μ} indicative of a magnetic loss is 0.1 or less at a frequency of 100 MHz.

15. A magnetic substance-containing insulator according to claim 11, wherein said insulator is a synthetic resin.

16. A magnetic substance-containing insulator according to claim 14, wherein said synthetic resin is at least one selected from the group consisting of an epoxy resin, a phenol resin, a polyimide resin, a polyester resin, a fluorine resin, a denatured polyphenylether resin, a bismaleimide triazine resin, a denatured polyphenylene oxide resin, a silicon resin, an acrylic resin, a benzocyclobutene resin, a polyethylene naphthalate resin, a polycycloolefin resin, a polyolefin resin, a cyanate ester resin, a melamine resin, an acrylic resin, and a liquid-crystal resin.

17. A magnetic substance-containing insulator according to claim 16, wherein a loss tangent tan δ_{μ} indicative of a magnetic loss is 0.1 or less at a frequency of 100 MHz.

18. A circuit board comprising at least the magnetic substance-containing insulator according to claim 11.

19. An electronic device comprising at least the circuit board according to claim 18.

20. An electronic component comprising at least the magnetic substance-containing insulator according to claim 11.

21. An electronic device comprising at least the electronic component according to claim 20.

22. A method of manufacturing a magnetic substance-containing insulator obtained by mixing together a resin varnish and a slurry in which a magnetic substance is dispersed in a solvent and by performing coating, drying, and firing, wherein a process of manufacturing said slurry comprises the steps of manufacturing a dispersion solvent in which a surfactant is added to said solvent and mixing magnetic substance fine powder to said dispersion solvent, the step of mixing said magnetic substance fine powder comprises the sub-steps of performing the screw stirring, irradiating an ultrasonic wave having a frequency of less than 100 kHz, and irradiating an ultrasonic wave having a frequency of 100 kHz or more.

23. A method of manufacturing a magnetic substance-containing insulator according to claim 22, wherein said firing is press firing performed under reduced pressure.
